(19) United States
(12) Patent Application Publication
(10) Pub. No.: US 2011/0096504 A1
(43) Pub. Date: Apr. 28, 2011

(54) Organic Electronic Components

(76) Inventor: Olaf Ruediger Hild, Radebeul (DE)

(21) Appl. No.: 12/673,219

(22) PCT Filed: Aug. 14, 2008
(86) PCT No.: PCT/EP08/06704

§ 371 Date: Jun. 10, 2010

(30) Foreign Application Priority Data
Aug. 14, 2007 (DE) 10 2007 038 324.1

(51) Int. Cl. H05K 7/20; H01J 7/24; H05B 37/02; G02F 1/15; H01J 1/62

(52) U.S. Cl. 361/704; 313/46; 315/291; 359/265; 313/504

(57) ABSTRACT

There is made available a substrate base and a cover element and also disposed at least partially between the substrate base and the cover element: a first electrode, an organic layer system which has at least one layer consisting of at least partially an organic material, and a second electrode. There are disposed at least partially between the substrate base and the cover element: a drying agent layer, which contains a dry material and also a thermally conductive material, and a thermally conductive layer, the drying agent layer and the thermally conductive layer being coupled to each other thermally.

The present invention relates to organic electronic components, in particular organic light emitting diodes (OLEDs) or organic solar cells. OLEDs hereby have an organic layer system which is generally constructed from a plurality of organic layers and is contacted by means of two electrodes. This applies likewise for organic solar cells. The present invention hereby deals in particular with the cooling of organic electronic components, with the generation of effects (for example achievement of colour changes or display of characters or symbols by OLEDs). The present invention deals furthermore with the protection (for extending the lifespan) of such organic electronic components.

Organic electronic components are known already from the state of the art: for example, it is common during the production of OLEDs to insert drying agents, such as zeolites or CaO-based systems, since the damaging effect of water on the OLEDs is already known. The same applies for organic solar cells. Furthermore, it is known that the temperature of the components influences the lifespan thereof, the performance thereof and the stability thereof. In operation, the result usually is a temperature increase in the components which has a negative effect on these properties, in particular also on the lifespan of the components.

In the case of the standard drying agents known from state of the art (CaO- and zeolite-containing products), it is known to glue on CaO-based drying agents in the form of adhesive pads. Zeolite-based products are usually applied as liquid drying agents (for example zeolite pastes) from a solution. The zeolites must hereby be activated before use thereof, which can be effected for example by IR radiation and/or by introducing into a vacuum.

As indicated already, the result can be degradation of the organic electronic components by light incidence. One cause is the formation of singlet oxygen by means of the light excitation of photosensitisers (for example phthalocyanines) and because of the energy transfer to the oxygen. This can present a problem in particular for exterior applications of OLEDs or of organic solar cells since the active surfaces are then subjected for a long time to sun radiation. Small quantities of oxygen already hereby suffice (which for example can penetrate through adhesive seams) in order to reduce significantly the lifespan of the components.

Finally, it is known from the state of the art to use colour foils, which can be glued for example onto the OLEDs, in order to achieve light effects.

It is the object of the present invention, based on the organic electronic components known from the state of the art, to extend the lifespan thereof in the simplest and most cost-effective manner possible. It is hereby in particular an object to improve the cooling of organic electronic components. Furthermore, the object of the present invention is to make available organic electronic components, such as in particular OLEDs, with which light effects can be achieved in a simple, favourable and flexible manner.

The above objects are achieved by an organic electronic component according to claim 1, by an organic electronic component according to claim 21, by an organic electronic component according to claim 27 and by a display according to claim 38. Advantageous embodiments can hereby be deduced from the respective dependent claims.

Furthermore, within the scope of the present invention, methods are made available (see claims 39 to 41) which can be used likewise within the scope of the above-mentioned object solution. Uses according to the invention are described in claim 42.

The basic idea of the solution to the above-mentioned objects is based, on the one hand, in integrating the drying and the cooling of the above-mentioned organic electronic components. A further basic idea of the present invention is to use photochromic and/or electrochromic layers for protecting the organic electronic components and/or for generating effects with such components.

The solution according to the invention is described subsequently in detail with reference to several embodiments. The individual features according to the invention represented hereby can occur not only in a combination, as is shown in the individual special advantageous embodiments, but can also be configured or used within the scope of the present invention in any other combination possibilities.

The organic electronic components according to the invention, which are described in detail with the subsequent embodiments, have above all the following advantages relative to the organic electronic components known from the state of the art:
The component design improved according to the invention increases the effect of measures for cooling; in particular, the heat conduction to corresponding cooling elements or cooling bodies is significantly improved. Not only rigid but also flexible or flexibly encapsulated components can dissipate heat better according to the invention.
In particular in the case of organic solar cells, the waste heat can be used according to the invention also for energy recovery.
The organic electronic components according to the invention are protected significantly better from lifespan-shortening light effect.
By means of the organic electronic components according to the invention, virtually any effects can be generated in a simple and cost-effective manner.
A significant improvement relative to the state of the art can be achieved by the present invention both against degradation by heat and against degradation by light, which plays a role in particular in the sought light densities of 1,000 cd/m² and more and also in the case of increasing integration requirement of the components in end products (ever greater importance is attached to heat production and dissipation as lifespan- and property-influencing parameters).
In particular by combining heat dissipation and absorption of moisture by means of the integrated provision of a thermally conductive material in the drying agent layer and also the subsequent coupling of this layer to a thermally conductive layer, significant progress relative to the state of the art is produced with respect to the above-mentioned aspects.

There are shown:

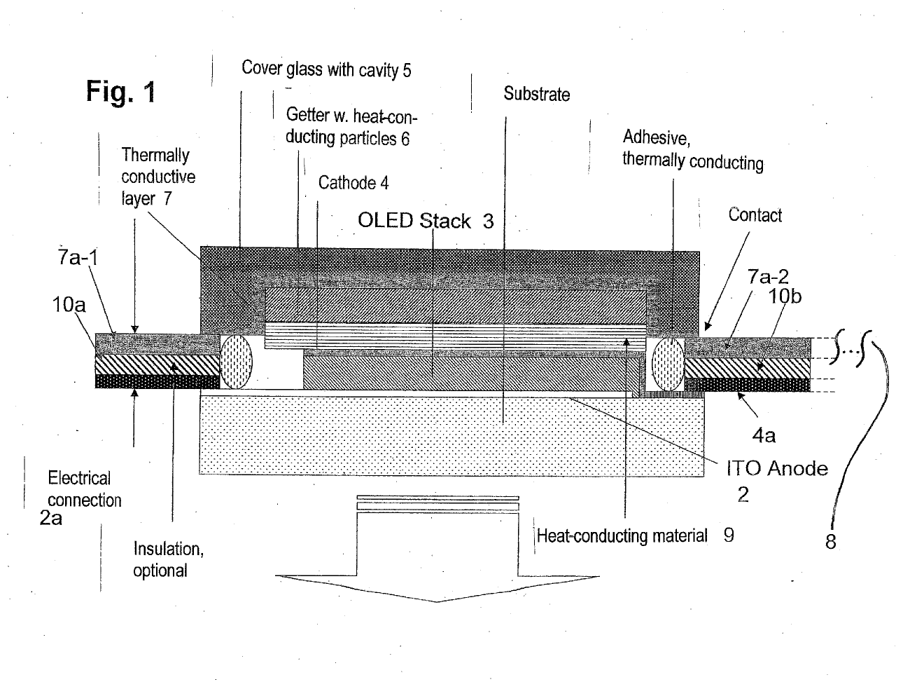

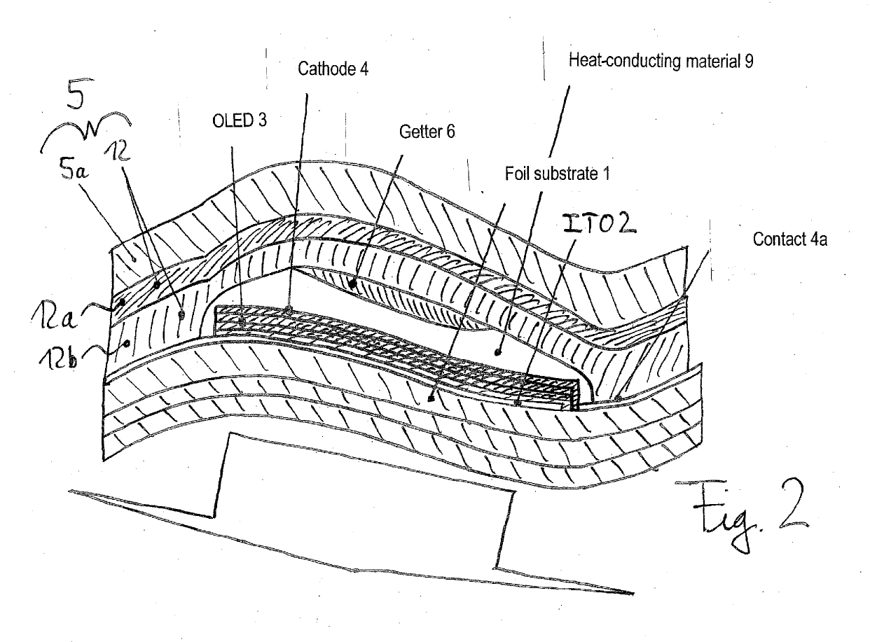

FIG. 1 a first organic electronic component of the invention in the form of an OLED.

FIG. 2 a flexible organic electronic component in the form of an OLED according to the invention.

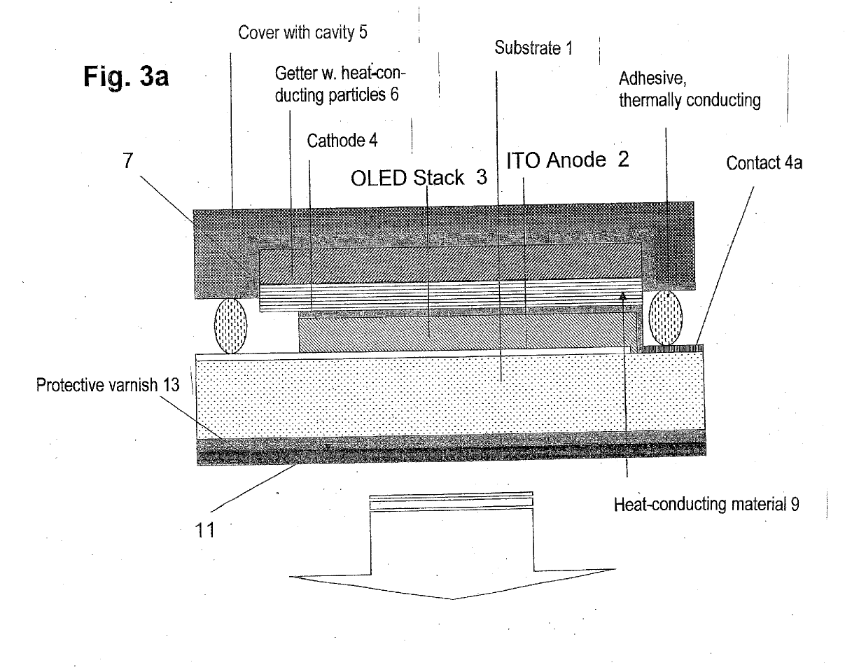

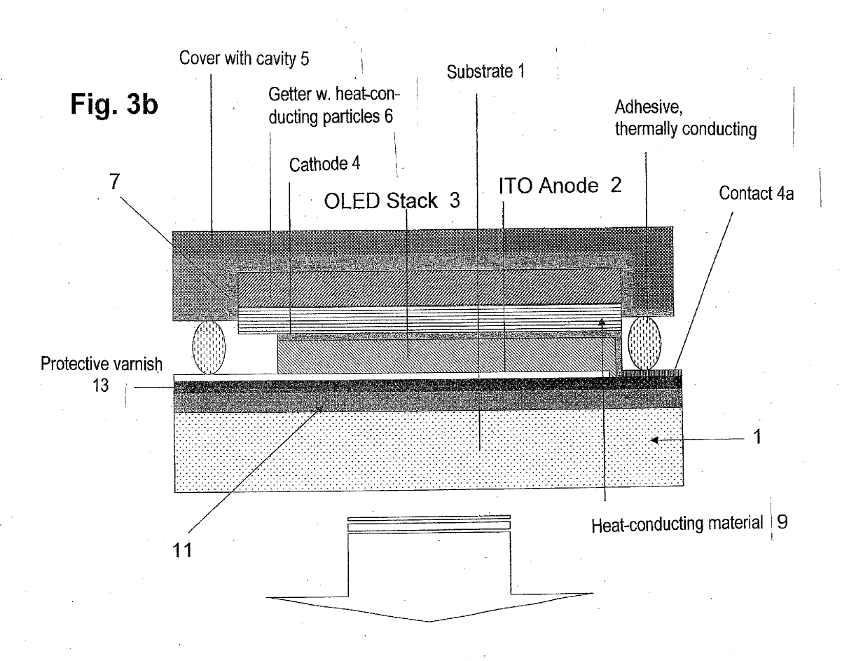

FIG. 3 a first and a second organic electronic component in the form of an OLED which has a photochromic and/or electrochromic layer.

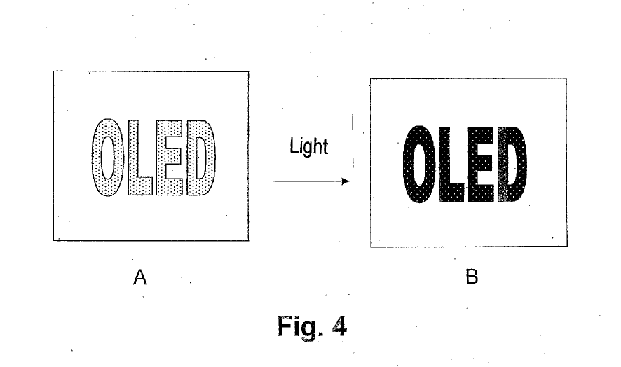

FIG. 4 an application case for an organic electronic component according to the invention in the form of an OLED.

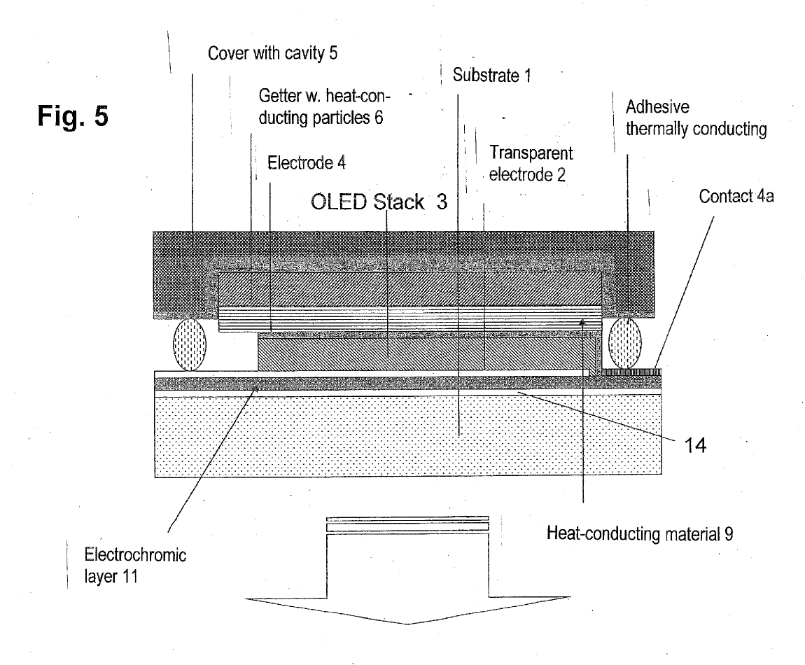

FIGS. 5 to 7 further electronic components in the form of OLEDs which have electrochromic layers.

FIG. 1 shows a first example of an organic electronic component according to the invention in the form of an organic light emitting diode.

A first electrode (here: transparent ITO anode) 2 is disposed on a glass substrate or a substrate base 1, abutting against this glass substrate. If it is merely mentioned in the course of the further description that a first element is disposed on a second element (and not that both elements also abut against each other), then this does not mean that the first element is disposed directly abutting against the second element, i.e. then another one or more further elements can be disposed readily between the first and the second element. An organic layer system 3 (OLED stack) is disposed on the first electrode 2 and abutting against the latter, which layer system has here a plurality of layers comprising organic materials (the precise structure of such an OLED stack is known to the person skilled in the art from the state of the art). The second electrode (cathode 4) is disposed on the OLED stack and abutting against the latter. The first and the second electrode 2, 4 are hereby configured as surface electrodes. A layer comprising a heat-conducting material, also termed second thermally conductive layer, is disposed on the second electrode 4 and abutting against the latter (layer 9). Directly abutting against the heat-conducting layer 9 (here a copper layer is concerned), a drying agent layer 6 (alternatively also termed getter layer) which contains a dry material and a thermally conductive material is disposed. This getter layer here comprises zeolite-containing materials, as are known to the person skilled in the art, a thermally conductive material in the form of metal particles being introduced however according to the invention into the zeolite layer. These metal particles are distributed uniformly over the entire layer thickness of the getter layer 6. The metal particles here have an average size of 10 to 100 μm and are contained with a volume proportion of approx. 30% in the getter layer 6. Copper was chosen here as material. The layer thickness of the getter layer 6 is 1 μm.

A first thermally conductive layer (copper layer) 7 is disposed directly abutting against the getter layer 6 and on the latter. A cover glass 5 with a cavity which seals the organic electronic component on the side situated opposite the substrate is disposed abutting against this thermally conductive layer 7 and on it. The cavity is hereby recessed in a cuboid shape into the cover glass 5 and receives the thermally conductive layer 7, the getter layer 6 and also the second heat-conducting material layer 9. The first thermally conductive layer 7 hereby covers the cavity of the cover glass 5 orientated towards the glass substrate 1 completely such that it completely surrounds the getter layer 6 on the upper side thereof and the narrow sides thereof and also contacts the heat-conducting material 9 laterally (on the narrow or end sides). The largest part of the first thermally conductive layer 7, the complete getter layer 6, the complete second heat-conducting material layer 9, the largest part of the cathode 4, the complete OLED stack 3 and also the largest part of the ITO anode 2 are hence sealed externally and protected by the cover glass 5 with cavity.

Viewed in the layer plane, the first thermally conductive layer 7 is now guided out laterally from the region of the cover glass in that two heat bridge connections 7a-1 and 7a-2 are configured. The heat bridge connections 7a are connected (for example with a copper line) to an external, passive cooling body 8. Hence the heat produced in the OLED stack 3 can be transferred via the heat-conducting material 9, which can also however be dispensed with, via the getter layer with heat-conducting particles 6, via the thermally conductive layer 7 in contact thermally with this layer and also the heat bridge connections 7a simply and efficiently to the cooling body 8 for cooling of the OLED stack 3. The adhesive which secures the cover glass 5 with cavity on the glass substrate 1 or on portions of the electrodes 2, 4 is configured here as thermally conductive adhesive and is in thermal contact with the thermally conductive layer 7 and also the heat bridge connections 7a-1 and 7a-2 thereof, which optimises the heat dissipation further.

The heat bridge connections 7a-1 and 7a-2 are provided on the lower side thereof (i.e. on the portion orientated towards the glass substrate 1) with an electrical insulation 10a, 10b. Directly abutting against this electrical insulation 10a, 10b, respectively electrical connections 2a, 4a of both electrodes 2, 4 are then configured (which hence are guided likewise laterally out of the region covered by the cover glass 5) in order to supply the suitable voltage to the OLED stack 3 via the first and second electrode 2, 4. The heat bridge connections 7a and the two electrical connection contacts 2a, 4a are hence coupled with the help of the electrically insulating portion 10a, 10b and form respectively common thermoelectric contactings of the organic layer system or of the OLED stack 3.

In the first embodiment, a thermally conductive layer 7 (which is configured here from copper, but can be configured also from aluminium, silver, nickel, calcium, magnesium, zinc, Sn, iron, gold or an alloy of several of these metals) is thus deposited according to the invention on the side of the cover glass 5 orientated towards the OLED 3. This layer 7 here has a thickness between 50 nm and 1 mm. According to the invention, the configuration of the getter layer 7, i.e. the application of a drying agent which, by introducing the thermally conductive materials (metal particles likewise made of the above-mentioned metals or alloys), ensures rapid removal of the heat from the OLED stack 3, is an essential aspect.

Optionally, an additional heat-conducting material layer 9 is configured here and is in contact with the OLED stack system 3 and the thermally conducting drying agent layer 6. In addition to the necessary electrical contacting of the component via the electrical connections 2a, 4a, the thermally conductive layer 7 is contacted via the heat bridge connections 7a (likewise made of copper) in order to enable optimal discharge of heat. To this heat bridge 7, 7a, the external cooling body structure 8 (the precise configuration of which is known to the person skilled in the art) is then thermally connected.

According to the application, an active cooling element can be used in addition in such a component according to the invention, in addition to the passive cooling shown. This can hereby concern for example a fan or a liquid-cooled system, as are known to the person skilled in the art. The active cooling element is then configured and/or disposed such that the already described heat removal is assisted in addition. In the case of organic solar cells, it can be advantageous furthermore to embed the described passive cooling into a liquid reservoir: by means of the removed heat, this liquid reservoir (for example water-filled) is then heated, the heated water or the heat thereof can then be used further (for example by subsequent connection of a system for hot water production or distribution). According to the application, embedding of this sort in a liquid reservoir can also be suitable for OLEDs or other organic electronic components which produce sufficient waste heat.

As already described, the electrodes 2 and 4 are configured by provision of the electrical connection contacts 2a and 4a, which are coupled by means of electrical insulations 10a and 10b to the heat bridge connections 7a-1 and 7a-2, such that a common electrical-thermal contacting of the OLED stack 3 is effected. In the present case, the heat-conducting layers are hence not voltage-conducting, therefore the heat-conducting layer 7 and the electrical parts are decoupled from each other. However, as is known to the person skilled in the art, alternative embodiments in which the heat-conducting layers 7, 7a can be used at the same time for the electrical contacting are also possible.

The heat discharge according to the invention can be assisted by the use of substrates 1 and/or cover glasses 5 which can conduct heat particularly well. These need not necessarily consist of glass, however it is necessary at least in the configuration as OLED or organic solar cell that one of the elements 1, 5 is at least partially transparent for light radiation of a desired wavelength.

FIG. 2 shows a further organic electronic component according to the invention in the form of a flexibly bendable organic light emitting diode.

Basically, the OLED shown in FIG. 2 is constructed like the one in FIG. 1 so that only the differences are described subsequently: the rigid glass substrate 1 in the embodiment in FIG. 1 is replaced here by a three-layer, flexible foil substrate 1. Likewise, the two electrodes 2, 4 and also the OLED stack are constructed from flexibly bendable or ductile materials.

Likewise, the rigid cover glass 5 with cavity in the embodiment of FIG. 1 together with thermally conductive layer 7 is replaced in the present case by a flexibly bendable cover element which comprises a flexibly bendable layer system. The flexibly bendable layer system 5 hereby has three layers disposed one above the other, however there can also be more or less than three layers (viewed in the direction from the side orientated away from the substrate to the side orientated towards the substrate): an uppermost, outermost cover layer comprising a carrier foil made of polypropylene, polyethylene, PI or PET (reference number 5a). Disposed abutting thereon there follows a heat-conducting foil 12 consisting of two layers (which is therefore a component of the cover element 5 here). The layer of this heat-conducting foil 12 orientated away from the foil substrate is constructed hereby as a metallised layer 12a comprising ductile Cu or Al. Abutting against the layer 12a there follows the second layer 12b of the heat-conducting foil 12 (which, according to the geometric configuration, abuts against the first electrode 2, the second electrode 4 and/or the foil substrate 1 in the regions surrounding the OLED stack 3). This layer 12b is configured here as PP-, PE-, PI-, PET- or polycarbonate layer.

The foil layer 12b hence forms a cavity in the region of the OLED stack 3, analogously to the case shown in FIG. 1. The OLED stack 3 and also a further heat-conducting material 9 surrounding said stack on the upper side thereof and also on the side faces thereof is disposed in this cavity. On this, i.e. between heat-conducting material 9 (configured here as liquid or pasty, non-conductive material which does not damage the OLEDs, e.g. resin or silicone oil) and layer 12b and abutting against the elements 9 and 12b, a getter layer 6 with introduced heat-conducting particles (analogously to the case shown in FIG. 1) is likewise disposed here. The getter layer 6 is optional here.

In the case of the flexible component, i.e. bendable over the entire surface, shown in FIG. 2, the encapsulation or the cover element 5 is replaced by a flexibly bendable layer system which has a heat-conducting foil 12. As an alternative hereto or also cumulatively hereto, the substrate can however also have a corresponding heat-conducting foil. As shown here, the heat-conducting foil can be the component of a multilayer system but it can also be the single component of the substrate or of the encapsulation. Preferably, at least one layer of the heat-conducting foil 12 is hereby metallised, this can serve not only for heat conduction but also for increasing the barrier properties relative to water and oxygen. In the configuration of the foil substrate 1 and of the flexible cover element 5, it should be noted that at least one of these two surface sides of the organic electronic component is transparent.

In addition, the further measures described already within the scope of FIG. 1 can be resorted to in the case shown in FIG. 2 (for example external cooling bodies and the like).

FIG. 3a shows a first embodiment of a further organic electronic component according to the invention in the form of an OLED which has a photochromic and/or electrochromic layer. FIG. 3b shows a further such embodiment in which this layer is disposed, in comparison to the case shown in FIG. 3a, on the surface side of the substrate base 1 orientated towards the OLED stack 3.

The basic structure of the OLED element shown in FIG. 3a is like that of the element shown in FIG. 1. For simplification, only the electrical contact 4a is indicated here, the electrical and thermal connections 2a, 7a-1 and 7a-2 (together with the elements 10a, 10b) are not shown here. A single difference is hence that the substrate 1, on the side orientated away from the cover 5, has a layer comprising a photochromic and/or electrochromic material 11 disposed abutting against the substrate 1. On said layer and abutting against the latter, a protective varnish layer 13 is disposed on the side orientated away from the substrate base 1, which protective varnish layer prevents mechanical damage to the layer 11.

Corresponding photochromic and/or electrochromic materials have already been described earlier for other application purposes and hence are known to the person skilled in the art:
H. Bonas, H. Dürr, “Organic photochromism”, Pure Appl. Chem., Vol. 73, No. 4, pp. 639-665, 2001.
G. Sonnez et al., “A Red, Green and Blue Polymeric Electrochromic Device; The Dawning of the PECD Era”, Appl. Chem. 2004, 116, 1523-1528.
R. Mortiner, “Organic electrochromic materials”, Electrochimica Acta 44 (1999), 2971-2981.
C. Lampert, “Chromogenic Smart materials”, materials today, March 2004, pp. 28-35.

With the help of a corresponding photochromic and/or electrochromic layer, different aspects, as described subsequently, can now be produced. With the help of photochromic layers (as are used for example in self-colouring spectacles), disruptive light wavelengths or lightwave length ranges can be filtered out specifically. For this purpose, a photochromic layer 11 which has a corresponding absorption band is applied. In the case of organic solar cells according to the invention (not shown here), this is only possible in a conditional manner since the light is required for energy production. However, it can also be sensible in this case, possibly as a function of the incident light intensity, to filter out a part of the wavelengths and/or a part of the light intensity.

In the case of OLEDs, this method can be applied in particular with those OLEDs which emit light only within a narrow wavelength range, as is the case for example with monochromic OLEDs. In addition, OLEDs for exterior applications, which are switched on for example at night, can be protected from sunlight within the entire light spectrum.

The photochromic materials used according to the invention can be applied in one layer or in a plurality of layers on the substrate. Also integration of a corresponding layer or integration of the photochromic material into the substrate or also into the encapsulation material (top-emitting OLEDs) is possible. A photochromic material can be used to cover the desired light spectrum, but likewise also a plurality of photochromic materials can be used which can be disposed then preferably in a plurality of layers disposed parallel to each other. Both individual layers and layer systems can hence be used.

Entirely analogously to the use of photochromic layers or photochromic layer systems, the use of electrochromic layers or electrochromic layer systems can be effected. The advantage thereby achieved is the possibility of active switching of the sun protection in that the corresponding electrochromic layer is provided with electrode contacts via which corresponding direct voltages can be applied. Thus, for example the desired light intensity (which impinges on an organic solar cell or which is emitted effectively by an organic light emitting diode) can be adjusted by the choice of voltage. The adjustment of a desired voltage also makes a stepped colour change possible on a suitable electrochromic system, for example on a polyaniline layer. In addition, it is thus possible short-term to switch the OLED or the solar cell “actively” for specific wavelengths or ranges. One application case is hereby a traffic light made of OLEDs which can make visible short-term for example the red signal by transparent switching of the electrochromic layer. In the case of an non-luminous signal, either the OLED can be switched off, the wavelength ranges of the OLED can be filtered out or a combination of both can be chosen. The current for a colour change is relatively low since once the colour state is adjusted it generally remains stable without further current flow.

By means of corresponding geometric structuring in the layer plane (in particular by local variation of the concentration of electrochromic material and/or photochromic material in the layer plane), effects can also be achieved, as described subsequently: thus colour changes can be achieved by applying a voltage to an electrochromic layer. These colour changes can be varied greatly by the voltage used according to the material system used. With this technique, also characters and symbols can be made visible or change in colour by applying the voltage as a result of the corresponding local structuring of the photochromic or electrochromic layer.

The thickness of the corresponding photochromic and/or electrochromic layer or layers hereby depends upon the colour effect which is to be achieved. If only small colour changes are intended to be achieved, then the corresponding layer should be chosen to be thinner. Thicker layers cause stronger colour effects. Alternatively hereto or also cumulatively hereto, the strength of the effect can be controlled however also via the concentration of the photochromic and/or electrochromic material in the corresponding layer. The colour effects are thereby dependent upon the wavelength and the intensity of the light used.

According to the invention, the light produced in the OLED can thereby be decoupled in that suitable layers are provided with suitable layer thicknesses, layer concentrations and layer materials in order to optimise such decoupling.

A corresponding effect generation can likewise be effected purely by photochromic layers. Thus, in addition to colour changes, also signs or symbols can be made visible, in that a corresponding layer structuring is provided. One application hereof is for example a radiation intensity display. According to the wavelength at which the photochromic layers react, only specific ranges and wavelengths can be responded to selectively thus by possibly secondary light sources. The OLED itself can also hereby produce the photochromic effect, i.e. the OLED emits the light causing the photochromic effect in the corresponding layer. For example, this can take place with structured OLEDs or corresponding displays with several colours which can be emitted (cf. FIG. 4, where the letters OLED were structured into a corresponding layer, in that a concentration of the photochromic material which is not equal to 0 was provided merely in these local regions): FIG. 4A shows the situation before light incidence of light of a suitable wavelength, FIG. 4B shows the case during radiation of light of the suitable wavelength, for example by the OLED stack 3 itself.

According to the invention, it is hereby possible of course to use both electrochromic and photochromic materials in different layers (the layers can hereby be disposed either one above the other or also adjacently). The layer thicknesses and/or the concentrations of the electrochromic and/or photochromic materials are hereby chosen corresponding to the sought application.

It is advantageous in particular to apply the electrochromic and/or photochromic layers on the inside of the component (i.e. on that side of the substrate 1 which is orientated towards the OLED stack 3) or between the substrate 1 and the OLED stack 3 (cf. FIG. 3b) since most of these materials must be protected from water and from air.

In addition, part of the electrodes can be jointly used according to the invention:

FIGS. 5 to 7 show such embodiments. These embodiments are basically configured like the embodiments shown in FIGS. 3a and 3b so that merely the differences are described subsequently. In the further example shown in FIG. 5, the electrochromic layer 11 is disposed abutting directly against the transparent ITO anode 2 (on the side thereof of this electrode orientated away from the OLED stack 3).

On the side of the electrochromic layer 11 orientated away from the transparent electrode 2, a further electrode 14 is then situated directly abutting against the layer 11. The electrochromic layer 11 is hence disposed in the manner of a sandwich between the transparent electrode 2 and the further electrode 14, so that, by means of these two electrodes 11, 14, a desired voltage can be applied to the electrochromic layer 11. The substrate 1 is then disposed abutting on the side of the further electrode 14 which is orientated away from the electrochromic layer 11 (said electrode being configured here likewise in a laminar form).

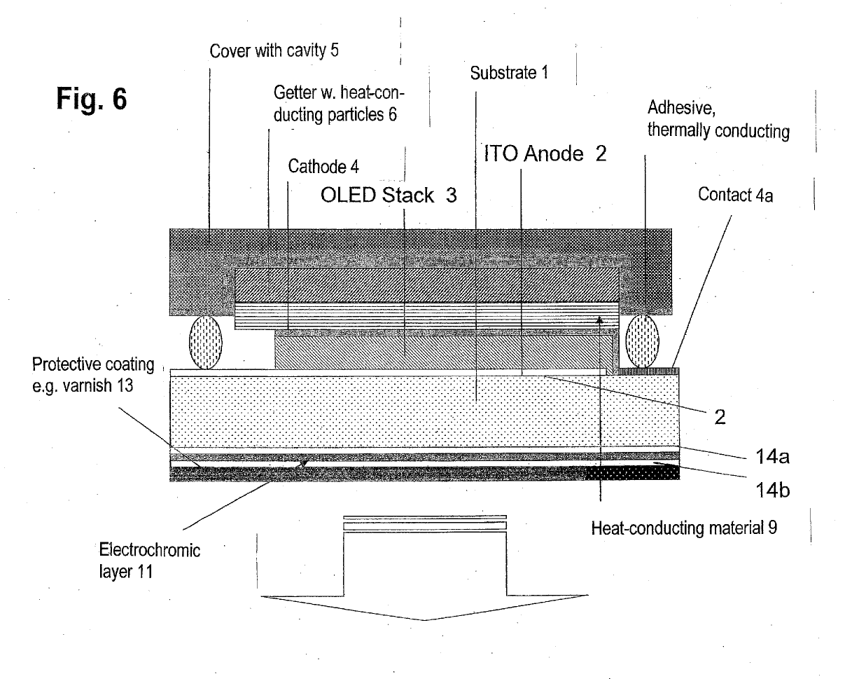

In the case shown in FIG. 6, the electrochromic layer 11 is disposed as in the case shown in FIG. 3a. On both surface sides thereof, two further electrodes 14a and 14b are however disposed such that a “sandwich” comprising substrate 1, first further electrode 14a, electrochromic layer 11, second further electrode 14b and protective varnish layer 13 results. The electrochromic layer 11 of two laminar electrodes 14a, 14b via which the suitable voltage can be applied to the electrochromic layer 11 is hence also included here.

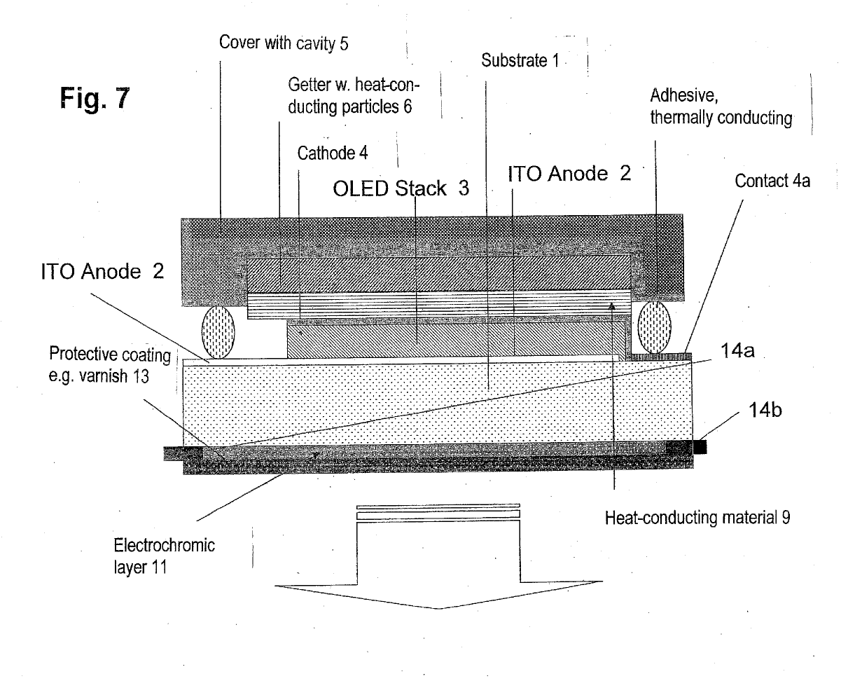

The case shown in FIG. 7 also resembles basically that which is shown in FIG. 3a. Instead of using laminar further electrodes 14a, 14b which are disposed in the manner of a sandwich, these two further electrodes are now however disposed in the layer plane of the electrochromic layer 11 laterally of the same so that the electrical field generated by them does not pass here through the electrochromic layer 11 perpendicular to the layer plane, instead the electrical field vector E is disposed here in the layer plane and hence perpendicular to the layer thickness or passes through the electrochromic layer 11 parallel to the layer plane.

In the first (in FIG. 5) shown case, the ITO anode 2 is hence likewise used for operation of the electrochromic layer 11.

The above-described possibilities can hence be used likewise with organic solar cells since, in addition to current generation, solar cells are also intended to have a certain aesthetic quality or likewise in combinations of transparent OLEDs on organic solar cells.

According to the invention, any written characters, such as company names or similar can hereby be made visible.

1-42. (canceled)

43. An organic electronic component, comprising:
a substrate base;
a cover element;
a first electrode;
a second electrode;
an organic layer system including at least one layer which at least partially consists of an organic material;
a drying agent layer including a dry material and a thermally conductive material; and
a thermally conductive layer,
wherein the first electrode, the second electrode and the layer system are at least partially disposed between the substrate base and the cover element, and
wherein the drying agent layer and the thermally conductive layer are (a) coupled to each other thermally and (b) at least partially disposed between the substrate base and the cover element.

44. The component of claim 43, wherein the component is one of an organic light emitting diode (OLED) and an organic solar cell.

45. The component of claim 43, wherein the thermally conductive material contains a metallic material, the metallic material being distributed in the dry material in a form of metal particles.

46. The component of claim 45, wherein the metal particles are distributed uniformly.

47. The component of claim 43, wherein the drying agent layer has a layer thickness of 10 nm to 5,000 p.m.

48. The component of claim 43, wherein the drying agent layer has a layer thickness of 200 nm to 10 μm.

49. The component of claim 45, wherein the metal particles have an average size of between 0.1 μm and 1,000 μm.

50. The component of claim 45, wherein the metal particles have an average size of between 1 μm and 200 μm.

51. The component of claim 43, wherein the thermally conductive material is contained with a volume proportion of between 5% and 70% in the drying agent layer.

52. The component of claim 43, wherein the thermally conductive material is contained with a volume proportion of between 20% and 40% in the drying agent layer.

53. The component of claim 43, wherein the thermally conductive material composed of at least one of Ni, Cu, Ag, Al, Ca, Mg, Zn, Sn, Fe, Au and an alloy of several of these materials.

54. The component of claim 43, wherein the dry material composed of at least one of (a) at least one zeolite material and (b) CaO.

55. The component of claim 43, wherein the thermally conductive layer has at least one of (A) at least one heat bridge connection using which the component can be contacted thermally and (B) at least one of (a) at least one metal and (b) at least one alloy.

56. The component of claim 55, further comprising:
a cooling body being in thermal contact with the heat bridge connection.

57. The component of claim 43, wherein the drying agent layer is disposed between the second electrode and the cover element.

58. The component of claim 43, wherein the drying agent layer and the thermally conductive layer are coupled to each other thermally by being disposed at least partially abutting against each other over the entire surface.

59. The component of claim 43, wherein the thermally conductive layer is disposed between the drying agent layer and the cover element.

60. The component of claim 43, wherein the first electrode is disposed on the substrate base, wherein the organic layer system is disposed on the first electrode, wherein the second electrode is disposed on the organic layer system, and wherein the cover element is disposed on the second electrode

61. The component of claim 60, wherein the first electrode is disposed on and abutting against the substrate base.

62. The component of claim 60, wherein the organic layer system is disposed on and abutting against the first electrode.

63. The component of claim 60, wherein the second electrode is disposed on and abutting against the organic layer system.

64. The component of claim 43, further comprising:
a second thermally conductive layer disposed between one of the first and second electrodes and the drying agent layer.

65. The component of claim 64, wherein the second thermally conductive layer abuts against at least one of (a) the first and second electrodes and (b) the drying agent layer.

66. The component of claim 64, wherein the second thermally conductive layer at least one of (1) includes at least one of (A) at least one metal and (B) at least one alloy and (2) is configured as a layer volume filled with one of a liquid and a pasty material.

67. The component of claim 43, further comprising:
an active cooling element adapted to cool the organic layer system.

68. The component of claim 67, wherein the cooling element includes at least one of a fan and a liquid cooling system.

69. The component of claim 43, further comprising:
a liquid reservoir configured to be at least partially filled with a cooling liquid,
wherein at least one of the drying agent layer, the first thermally conductive layer and the second thermally conductive layer are at least partially embedded in the liquid reservoir.

70. The component of claim 43, wherein at least one of (a) the first electrode has a first electrical connection contact and (b) the second electrode has a second electrical connection contact.

71. The component of claim 70, wherein the thermally conductive layer has at least one heat bridge connection using which the component is configured to be contact thermally and wherein at least one of the first and second electrical connection contacts is coupled, via an electrically insulating portion, to the at least one heat bridge connection in order to configure a common thermoelectric contacting of the organic layer system.

72. The component of claim 43, wherein at least one of the substrate base and the cover element is comprises of a material with a coefficient of thermal conduction of between 0.1 watt/(m·Kelvin) and 500 watt/(m·Kelvin).

73. The component of claim 43, wherein at least one of the substrate base and the cover element is comprises of an electrically non-conducting material.

74. The component of claim 43, wherein at least one of the substrate base and the cover element is comprises of glass.

75. The component of claim 43, wherein at least one of the substrate base and the cover element is at least partially transparent.

76. The component of claim 43, wherein at least one of the substrate base and the cover element includes at least one flexibly bendable layer system which has at least one further layer, at least one of the at least one further layer including a heat-conducting foil.

77. The component of claim 76, wherein the flexibly bendable layer system includes a metallized layer.

78. The component of claim 77, wherein the heat-conducting foil is metallized in order to configure the metallized layer.

79. A flexibly bendable organic electronic component, comprising:
a flexibly bendable substrate base;
a flexibly bendable cover element;
a flexibly bendable first electrode;
a flexibly bendable second electrode;
a flexibly bendable organic layer system including at least one layer, the layer at least partially including an organic material, the first electrode, the layer system and the second electrode being disposed at least partially between the substrate base and the cover element; and
a flexibly bendable layer system including at one layer,
wherein at least one of the substrate base and the cover element includes the flexibly bendable layer system, and
wherein at least one of the at least one layer of the flexibly bendable layer system includes a heat-conducting foil.

80. The component of claim 79, wherein the component is one of an organic light emitting diode (OLED) and an organic solar cell.

81. The component of claim 79, wherein the flexibly bendable layer system comprises of a metallized layer.

82. The component of claim 81, wherein the heat-conducting foil is metallized in order to configure the metallized layer.

83. The component of claim 21, further comprising:
a flexibly bendable drying agent layer including a dry material and a thermally conductive material; and
a flexibly bendable thermally conductive layer,
wherein the drying agent layer and the thermally conductive layer are at least partially disposed between the substrate base and the cover element, the drying agent layer and the thermally conductive layer being coupled to each other thermally.

84. The component of claim 83, wherein the heat-conducting foil configures the thermally conductive layer.

85. An organic electronic component, comprising:
a substrate base;
a cover element;
a first electrode;
an organic layer system including at least one layer, the at least one layer at least partially including an organic material;
a second electrode; and
a further layer system including at least one further layer, the at least one further layer including at least one of an electrochromic layer and a photochromic layer, the electrochromic layer comprising of at least one electrochromic material, the photochromic layer comprising of at least one photochromic material,
wherein the first electrode, the organic layer system and the second electrode are at least partially disposed between the substrate and the cover element.

86. The component of claim 85, wherein the component is one of an organic light emitting diode (OLED) and an organic solar cell.

87. The component of claim 85, wherein the further layer system includes a plurality of at least one of the electrochromic layers and the photochromic layers with a respectively different light absorption spectrum.

88. The component of claim 85, wherein the component is the OLED, at least one of the at least one electrochromic material and the at least one photochromic material absorbing light of a wavelength range outwith a wavelength range emitted by the organic layer system of the OLED.

89. The component of claim 85, wherein the component is the OLED, at least one of the at least one electrochromic material and the at least one photochromic material is chosen such that a wavelength of an absorption maximum of at least one of the at least one photochromic material and the at least one electrochromic material differs from a wavelength of an emission maximum of a wavelength range emitted by the organic layer system of the OLED by at least 10% relative to the wavelength of the absorption maximum.

90. The component of claim 85, wherein the component is the OLED, at least one of the at least one electrochromic material and the at least one photochromic material is chosen such that a wavelength of an absorption maximum of at least one of the at least one photochromic material and the at least one electrochromic material differs from a wavelength of an emission maximum of a wavelength range emitted by the organic layer system of the OLED by at least 25% relative to the wavelength of the absorption maximum.

91. The component of claim 85, wherein the component is the OLED, at least one of the at least one electrochromic material and the at least one photochromic material is chosen such that a wavelength of an absorption maximum of at least one of the at least one photochromic material and the at least one electrochromic material differs from a wavelength of an emission maximum of a wavelength range emitted by the organic layer system of the OLED by at least 50% relative to the wavelength of the absorption maximum.

92. The component of claim 85, wherein the component is the OLED, at least one of the at least one electrochromic material and the at least one photochromic material is chosen such that a wavelength of an absorption maximum of at least one of the at least one photochromic material and the at least one electrochromic material differs from a wavelength of an emission maximum of a wavelength range emitted by the organic layer system of the OLED by at least 100% relative to the wavelength of the absorption maximum.

93. The component of claim 85, wherein the further layer system is disposed on one of (A) a side of the substrate base orientated towards the cover element and (B) a side of the cover element orientated towards the substrate base.

94. The component of claim 95, wherein the further layer system is abutting one of the cover element and the substrate base.

95. The component of claim 85, wherein the further layer system is disposed on one of (A) a side of the substrate base orientated away from the cover element and (B) a side of the cover element orientated away from the substrate base.

96. The component of claim 95, wherein the further layer system is abutting one of the cover element and the substrate base.

97. The component of claim 85, wherein the further layer system is disposed integrated in one of the cover element and the substrate base.

98. The component of claim 85, wherein the further layer system includes the electrochromic layer and two electrodes, the electrochromic layer being contacted electrically using the two electrodes.

99. The component of claim 85, wherein the at least one further layer is structured in a layer plane.

100. The component of claim 85, wherein the at least one further layer is structured in a layer plane by varying a local concentration of at least one of the at least one electrochromic material and the at least one photochromic material.

101. The component of claim 85, wherein the further layer system includes a plurality of the structured electrochromic layers and the structured photochromic layers which are disposed perpendicular to a layer plane one above the other.

102. The component of claim 85, wherein the further layer system includes a plurality of the structured electrochromic layers and the structured photochromic layers which are disposed perpendicular to a layer plane one above the other, the layers being structured respectively differently.

103. The component of claim 85, wherein the at least one electrochromic material contains polyaniline.

104. The component of claim 85, wherein at least one of the electrochromic layer and the photochromic layer has a thickness of 50 nm to 1 mm.

105. The component of claim 85, wherein at least one of the at least one electrochromic material and the at least one photochromic material is present in a matrix.

106. The component of claim 85, wherein the organic layer system has at least one layer which is structured in a layer plane.

107. The component of claim 85, wherein the organic layer system has at least one layer which is structured in a layer plane by varying a local concentration of an organic material thereof.

108. The component of claim 85, further comprising:
a drying agent layer including a dry material and a thermally conductive material; and
a thermally conductive layer,
wherein the drying agent layer and the thermally conductive layer are at least partially disposed between the substrate base and the cover element, the drying agent layer and the thermally conductive layer being coupled to each other thermally.

109. A display, comprising:
a plurality of organic electronic components disposed in a two-dimensional matrix in a form of OLEDs,
wherein each of the components includes a substrate base; a cover element; a first electrode; a second electrode; an organic layer system including at least one layer which at least partially consists of an organic material; a drying agent layer including a dry material and a thermally conductive material; and a thermally conductive layer,
wherein the first electrode, the second electrode and the layer system are at least partially disposed between the substrate base and the cover element, and
wherein the drying agent layer and the thermally conductive layer are (a) coupled to each other thermally and (b) at least partially disposed between the substrate base and the cover element.

110. A display, comprising:
a plurality of flexibly bendable organic electronic components disposed in a two-dimensional matrix in a form of OLEDs,
wherein each of the flexibly bendable organic electronic components includes a flexibly bendable substrate base; a flexibly bendable cover element; a flexibly bendable first electrode;
a flexibly bendable second electrode; a flexibly bendable organic layer system including at least one layer, the layer at least partially including an organic material, the first electrode, the layer system and the second electrode being disposed at least partially between the substrate base and the cover element; and a flexibly bendable layer system including at one layer,
wherein at least one of the substrate base and the cover element includes the flexibly bendable layer system, and
wherein at least one of the at least one layer of the flexibly bendable layer system includes a heat-conducting foil.

111. A display, comprising:
a plurality of organic electronic components disposed in a two-dimensional matrix in a form of OLEDs,
wherein each of the components includes a substrate base; a cover element; a first electrode; an organic layer system including at least one layer, the at least one layer at least partially including an organic material; a second electrode; and a further layer system including at least one further layer, the at least one further layer including at least one of an electrochromic layer and a photochromic layer, the electrochromic layer comprising of at least one electrochromic material, the photochromic layer comprising of at least one photochromic material, and
wherein the first electrode, the organic layer system and the second electrode are at least partially disposed between the substrate and the cover element.

112. A method for protecting an organic electronic component from a light incidence of at least one of (A) a defined spectral range and (B) above a predefined intensity, comprising:
applying a temporally variable electrical voltage to an organic electronic component which includes a substrate base; a cover element; a first electrode; an organic layer system including at least one layer, the at least one layer at least partially including an organic material; a second electrode; and a further layer system including at least one further layer, the at least one further layer including at least one of an electrochromic layer and a photochromic layer, the electrochromic layer comprising of at least one electrochromic material, the photochromic layer comprising of at least one photochromic material,
wherein the first electrode, the organic layer system and the second electrode are at least partially disposed between the substrate and the cover element.

113. The method of claim 112, wherein the component is one of an organic light emitting diode (OLED) and an organic solar cell.

114. The method of claim 112, wherein the electrical voltage is varied as a function of at least one of (A) time of day and (B) a light intensity impinging on the component.

115. A method for making at least one of a structure, a symbol and a character temporarily visible with an organic light emitting diode (OLED), comprising:
applying a temporally variable electrical voltage to an organic electronic component which includes a substrate base; a cover element; a first electrode; an organic layer system including at least one layer, the at least one layer at least partially including an organic material; a second electrode; and a further layer system including at least one further layer, the at least one further layer including at least one of an electrochromic layer and a photochromic layer, the electrochromic layer comprising of at least one electrochromic material, the photochromic layer comprising of at least one photochromic material,
wherein the first electrode, the organic layer system and the second electrode are at least partially disposed between the substrate and the cover element.
